(19) United States
(12) Patent Application Publication
(10) Pub. No.: US 2026/0289036 A1
(43) Pub. Date: Sep. 24, 2026

(54) AUTOMATED FEATURE-PARAMETER MANAGEMENT FOR PRODUCT LINE ENGINEERING

(71) Applicants: FCA US LLC, Auburn Hills, MI (US); Stellantis Auto SAS, Poissy (FR)

(72) Inventors: Ned A Troxel, Auburn Hills, MI (US); Carlos E Marin Suarez, Mexico City (MX)

(21) Appl. No.: 19/086,300

(22) Filed: Mar. 21, 2025

(51) Int. Cl. G06F 30/20

(52) U.S. Cl. CPC G06F 30/20

(57) ABSTRACT

An automated feature-parameter management system and method. The system includes: a data storage system for storing product feature model data, operational parameter model data, and feature-parameter mapping model data; a computer system configured to: obtain bill-of-features data for a product using the product feature model data, wherein the bill-of-features data indicates a first set of features for the product; obtain first feature-parameter mapping data for the set of features for the product, wherein the first feature-parameter mapping data is obtained data from the feature-parameter mapping model data stored in the data storage system; and determine operational parameter data based on the operational parameter model data and the first feature-parameter mapping data.

### FIELD

The present disclosure relates to managing and facilitating product feature definitions, relationships, and aspects as they relate to parameters configured during manufacturing, such as calibration information or other operational parameters.

### BACKGROUND

The increasing complexity of modern vehicles, driven by the proliferation of software-defined features and interconnected electronic control units (ECUs), has necessitated the development of robust frameworks for managing data across various stages of the product lifecycle. Automakers and suppliers rely on systems like Product Lifecycle Management (PLM) platforms, such as ENOVIA, and feature or operational parameter configuration tools to handle different aspects of this complexity. While these systems serve distinct purposes—e.g., ENOVIA focusing on high-level lifecycle management and operational parameter configuration tools focusing on detailed parameter configuration and states—they operate isolated from one another (each as a silo), resulting in challenges in synchronizing and corresponding data, as well as maintaining traceability across the development process.

Conventional systems primarily focus on parameter management within a specific operational domain, such as ECU configuration, but lack inherent mechanisms for mapping and aligning these parameters with lifecycle data stored in systems like ENOVIA. This creates a gap in traceability between design intent and implementation (between product feature and operational parameters thereof), necessitating manual, tedious consideration in order to validate that the features delivered in a vehicle aligned with their original specifications and requirements.

Additionally, the scalability of conventional frameworks is increasingly strained by the growing number of features and interdependencies in modern vehicles. Managing and synchronizing large volumes of parameter data across multiple ECUs and product lines can introduce bottlenecks, particularly when changes are required to accommodate updates in design or regulatory standards. The reliance on manual processes for defining and managing parameter mappings further exacerbates these challenges, increasing the risk of errors, inconsistencies, and delays in feature deployment.

A critical drawback of existing solutions is their limited capability for real-time synchronization between PLM platforms and ECU configuration systems. Changes made to high-level requirements or designs in ENOVIA often require time-intensive manual updates to corresponding parameters in an operational parameter model (e.g., PRO.X.I. used by Stellantis™), leading to potential discrepancies that can impact both the quality and safety of the final product. Furthermore, the lack of direct lineage tracking between lifecycle data and parameter configurations impedes the ability to validate features, trace issues, or ensure compliance with stringent automotive standards.

### SUMMARY

In at least some implementations, an automated feature-parameter management system is provided. The automated feature-parameter management system includes: a data storage system being comprised of non-transitory, computer-readable memory, and being used for storing product feature model data, operational parameter model data, and feature-parameter mapping model data; and a computer system having at least one electronic processor and memory storing computer instructions. The computer system, when the computer instructions are executed by the at least one processor, is configured to: obtain bill-of-features data for a product using the product feature model data, wherein the bill-of-features data indicates a first set of features for the product; obtain first feature-parameter mapping data for the set of features for the product, wherein the first feature-parameter mapping data is obtained data from the feature-parameter mapping model data stored in the data storage system; and determine operational parameter data based on the operational parameter model data and the first feature-parameter mapping data.

In at least some implementations, a method of determining operational parameter data for a product with a set of features is provided. The method includes: obtaining bill-of-features data for a product using product feature model data, wherein the bill-of-features data indicates a first set of features for the product; obtaining first feature-parameter mapping data for the set of features for the product, wherein the first feature-parameter mapping data is obtained data from feature-parameter mapping model data; and determining operational parameter data based on operational parameter model data and the first feature-parameter mapping data.

Further areas of applicability of the present disclosure will become apparent from the detailed description, claims and drawings provided hereinafter. It should be understood that the summary and detailed description, including the disclosed embodiments and drawings, are merely exemplary in nature intended for purposes of illustration only and are not intended to limit the scope of the invention, its application or use. Thus, variations that do not depart from the gist of the disclosure are intended to be within the scope of the invention.

### BRIEF DESCRIPTION OF THE DRAWINGS

FIG. 1 is a diagrammatic depiction of an automated feature-parameter management system, according to one embodiment;

FIG. 2 is a diagrammatic depiction of portions of the automated feature-parameter management system of FIG. 1, including a feature-parameter mapping model generation framework, according to one embodiment;

FIG. 3 is a flowchart illustrating a method of generating feature-parameter mapping data and a report concerning the feature-parameter mapping model, according to one embodiment;

FIG. 4 is a diagrammatic depiction of an example in which feature-parameter mapping data is being used to map product feature model data to operational parameter model data;

FIG. 5 is a flowchart illustrating a method of updating product feature model data, operational parameter model data, and/or feature-parameter mapping data and generating a report concerning the update, according to one embodiment; and

FIG. 6 is a flowchart illustrating a method of automatically determining operational parameter(s) for a product and providing the operational parameter(s) to an operator, according to one embodiment.

### DETAILED DESCRIPTION

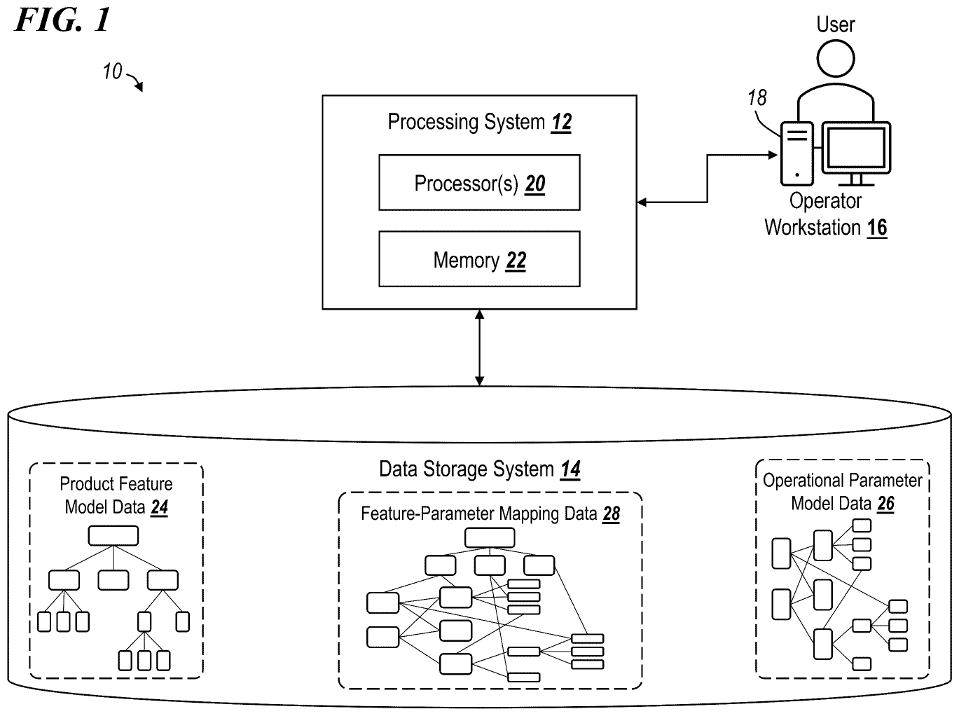

With reference now to FIG. 1, there is shown an automated feature-parameter management system 10 for facilitating product line engineering (PLE) of a product to be manufactured. The automated feature-parameter management system 10 includes a computer or processing system 12, a data storage system 14, and an operator workstation 16 having a client computer 18 for use by an operator, such as for viewing information or results of the automated feature-parameter management system 10. Although the automated feature-parameter management system 10 is shown and described as having particular components and configurations, it will be appreciated that any suitable configuration and componentry may be used, according to various embodiments.

Product Line Engineering (PLE), as defined by the International Organization for Standardization (ISO) 26550, is a systematic methodology for managing the development of a family of related products by leveraging commonalities across their design and production processes. In the automotive sector, PLE is particularly valuable for original equipment manufacturers (OEMs) that produce diverse vehicle models with varying configurations. By adopting a platform-based design, PLE reduces development time and effort, improves product quality, and ensures consistency across the product line. The framework consists of four interrelated disciplines that collectively enable OEMs to streamline product lifecycle management and enhance their ability to respond to market demands.

The first discipline in the PLE framework generally involves the development of a centralized feature catalogue, which serves as a comprehensive repository of all features available across the product family. Each feature in the catalogue is systematically modeled, including its dependencies, constraints, and potential interactions with other features. By capturing this information, the feature catalogue ensures that features are accurately defined, integrated, and consistently applied throughout the development process. For automotive OEMs, the feature catalogue supports the consistent representation of functionality and options available in various vehicle models, providing a foundation for efficient design and production.

The second discipline in the PLE framework focuses on managing the feature selections for specific applications through bills of features (or bills-of-features). Each product variant or vehicle model is represented by a bill of features, which specifies the subset of features selected from the feature catalogue, which may even vary amongst vehicles of the same vehicle model, in some instances. This process ensures that every product instance adheres to the constraints and dependencies defined in the feature catalogue. By maintaining a clear and structured bill of features for each vehicle configuration, OEMs can effectively manage product variability while ensuring compatibility and consistency across the product line. This alignment between customer/product requirements, engineering specifications, and production workflows enhances the overall efficiency of the product development lifecycle.

The third discipline in the PLE framework involves designing engineering assets as supersets that incorporate all possible variations required for the product line. These engineering assets include requirements, design models, software components, and testing artifacts, each designed with specific variation points. Variation points are directly linked to the feature catalogue so that dynamic configuration based on the feature selections defined in the bills of features may be made. Such an approach allows automotive OEMs to reuse engineering assets across multiple vehicle models, significantly reducing development effort and improving scalability. By embedding variability within the supersets, the system ensures that each asset can be customized to meet the specific needs of individual vehicle configurations.

The final discipline in the PLE framework involves the automatic generation and configuration of product asset instances. A configurator tool evaluates the bill of features for a specific product variant and applies it to the shared asset supersets. This process dynamically selects and configures the required assets, producing a complete and validated set of product-specific engineering artifacts. These product asset instances are the finalized deliverables necessary for manufacturing and supporting a particular vehicle model. According to embodiments, through automating this process, OEMs can reduce errors, ensure consistency, and accelerate the delivery of new vehicle models to market.

By integrating these four disciplines of the PLE framework, automotive OEMs are able to manage the complexity of modern vehicle development more effectively. This systematic approach ensures that shared assets are leveraged efficiently, that feature variability is managed consistently, and that engineering deliverables align with customer and market requirements. The adoption of PLE supports scalability, reduces time-to-market, and enhances the overall quality and reliability of automotive products.

However, as discussed above, current methodologies often lack the capability to effectively integrate and synchronize high-level PLM data with low-level feature configurations, leading to potential discrepancies and inefficiencies in the product development process. Given these limitations, there is a clear need for a system that can seamlessly map, synchronize, and validate parameter data between PLM platforms like ENOVIA and feature configuration systems like PRO.X.I. Such a system would provide a unified framework for managing feature lifecycle data, enhancing consistency, traceability, and scalability across the development process. By bridging the gap between high-level design and low-level implementation, this approach would enable automakers to address the growing complexity of software-defined vehicles more efficiently, reducing time-to-market, minimizing errors, and ensuring compliance with safety and regulatory requirements.

The processing system 12 is used for carrying out various functionality described herein, including the method (or at least steps or aspects thereof), as discussed below. The processing system 12 includes at least one processor 20 and memory 22 storing computer instructions accessible by the at least one processor 20. The at least one processor 20 is configured to execute the computer instructions so as to cause performance/execution of the functionality discussed herein attributed to the automated feature-parameter management system 10.

The at least one processor 20 refers to one or more electronic processors, and any one or more of these processors or other processors discussed herein may be implemented as any suitable electronic hardware that is capable of processing computer instructions and may be selected based on the application in which it is to be used. Examples of types of processors that may be used include central processing units (CPUs), graphics processing units (GPUs), field-programmable gate arrays (FPGAs), application specific integrated circuits (ASICs), microprocessors, microcontrollers, etc.

The memory 22 refers to one or more non-transitory, computer-readable memory devices (or memories), and any of these memories or other memory discussed herein may be implemented as any suitable type of memory that is capable of storing data or information in a non-volatile manner and in an electronic form so that the stored data or information is consumable by the processor. The memory 22 may be any of a variety of different electronic memory types and may be selected based on the application in which it is to be used. Examples of types of memory that may be used include magnetic or optical disc drives, ROM (read-only memory), solid-state drives (SSDs) (including other solid-state storage such as solid-state hybrid drives (SSHDs)), other types of flash memory, hard disk drives (HDDs), non-volatile random access memory (NVRAM), etc.

The data storage system 14 is used for storing various information, values, etc. in electronic form, and is implemented using one or more non-transitory, computer-readable memory devices, such as those discussed in connection with the memory 22. In some embodiments, the memory 22 may be used as (or at least as a part of) the memory used for the data storage system 14; however, in other embodiments, the memory devices for the memory 22 and the data storage system 14 may be different.

The data storage system 14 is show as storing three sets of data, including product feature model data 24, operational parameter model data 26, and feature-parameter mapping data 28.

The product feature model data 24 is data representing a collection of product features, including configurable features, across a family of related products. For example, in the context of an automotive OEM, a feature catalog may include a representation of the configurable features available across a product line, such as a family of sedans or SUVs. Core features may encompass the base engine type, such as a 2.0 L inline-4, which is shared across all models, while optional features might include a turbocharged variant or a hybrid drivetrain. Variant features could include choices for drivetrain configurations, such as front-wheel drive, all-wheel drive, or rear-wheel drive, with dependencies ensuring that certain drivetrain options are only available with specific engines or trim levels. Additional optional features may include, for example, infotainment systems, where customers can select between a standard 8-inch display, a 12-inch touchscreen with navigation, or a premium system with advanced connectivity, with constraints that prevent the inclusion of incompatible options. The feature catalog may also include information about relationships between features, such as data representing constraints amongst different features, such as, for example, where a premium sound system requires a higher-end infotainment system or where certain advanced driver-assistance systems, like adaptive cruise control, are only available on higher trim levels. The product feature model data 24 may, in one embodiment, also include variability points, such as the choice of exterior paint colors, interior upholstery materials, and wheel designs, all governed by rules to ensure compatibility with specific models or packages, for example.

The operational parameter model data 26 is data representing operational parameter definitions used for software or otherwise for input into one or more sensors or electronic control units (ECUs), such as, for example, speed thresholds for adaptive cruise control, idle RPM settings for various engine configurations, or calibration values for torque limits in electronic stability control systems. This data is configured post-integration, typically at the vehicle assembly plant, and ensures that each system operates within its designed parameters based on the specific vehicle configuration. For instance, the operational parameter model data may include region-specific configurations, such as emission control parameters to meet local regulatory standards, or parameters for seatbelt warning chimes tailored to country-specific legal requirements. Additionally, it may define allowable ranges, default values, and units for each parameter, along with dependency rules to ensure compatibility between systems. For example, the calibration of a hybrid powertrain's energy management system may depend on battery capacity and drivetrain configuration as defined in the feature model. By enabling fine-tuned adjustments and ensuring interoperability among software and hardware components, operational parameter model data supports accurate functionality across diverse vehicle variants, facilitates compliance with regulatory and safety standards, and allows for post-production updates or calibration when necessary.

The feature-parameter mapping data 28 is used for providing a correspondence or mapping between the product feature model data 24 and the operational parameter model data 26. The feature-parameter mapping data 28 is generated by defining and integrating a product feature model and an operational parameter model, establishing relationships and dependencies between features and parameters. In the present embodiment, automated tools or methodologies, such as pure::variants, are used for generating the feature-parameter mapping data 28 while ensuring consistency, scalability, and alignment with product configurations.

At least in some embodiments, such as is often the case for automotive original equipment manufacturers (OEMs) and/or suppliers, inherent differences between the product feature model and the operational parameter model provide for a complicated, convoluted correspondence between data of the product feature model and that of the operational parameter model. Indeed, such a mapping is not generatable through merely considering the product feature model and the operational parameter model, as relationships between the different datasets are only determinable based on specialized domain knowledge. As used herein, the term “domain knowledge” refers to information learned by a tradesperson or other skilled individual within a particular trade or field.

In at least one embodiment, a domain expert (i.e., a human with specialized domain knowledge learned from schooling, other formal learning, experience, or some combination thereof) is situated at the client computer 18 and inputs from the domain expert are provided to the client computer 18, such as through the user of a computer keyboard and/or mouse, microphone, etc. In one embodiment, the specialized domain knowledge is directly indicative of data that connects, relates, or otherwise maps or provides a correspondence between the product feature model data 24 and the operational parameter model data 26.

In one embodiment, pure::variants™ is used for generating feature-parameter mapping data as described, the process begins with defining the product feature model. The software tool, pure::variants™, is used in the field of systems engineering and product line management to model, manage, and configure variability across complex systems, enabling the efficient customization and generation of product variants while ensuring consistency and compliance with defined constraints and dependencies. This tool may be used via a plugin to the integrated development environment (IDE), Eclipse™.

In embodiments, generating the feature-parameter mapping data 28 includes creating a feature model in pure::variants to represent the various product features. These include core features, such as base engine types like a 2.0 L inline-4, optional features like turbocharged engines or hybrid drivetrains, and variant features, such as drivetrain configurations including front-wheel drive, all-wheel drive, or rear-wheel drive. The model also incorporates constraints to maintain compatibility, such as ensuring a premium sound system requires a high-end infotainment system, or that adaptive cruise control is only available on higher trim levels. Variability points, such as exterior paint colors, interior upholstery, and wheel designs, are governed by rules ensuring they align with specific models or packages. Once the feature model is fully defined, it is exported in a format supported by pure::variants™ to facilitate integration.

The next step in generating the feature-parameter mapping data 28 includes defining the operational parameter model, which contains data about operational parameters like speed thresholds for adaptive cruise control, torque limits for stability control systems, or idle RPM settings for various engine configurations, for example. This operational parameter model may include region-specific configurations to meet local regulatory standards, such as, for example, emission control parameters or seatbelt warning chimes tailored to country-specific laws. The operational parameter model may also specify allowable ranges, default values, and units for each parameter, along with dependency rules to ensure system compatibility. For example, the calibration of a hybrid powertrain's energy management system might depend on battery capacity and drivetrain configuration. After the operational parameter model is created (represented as the operational parameter model data), such data is also exported for integration into the mapping process.

The feature-parameter mapping process involves defining correspondences between the product feature model and the operational parameter model. In the present embodiment, the mapping capabilities of pure::variants are used to generate a mapping model that links product features with their associated operational parameters. For example, selecting a turbocharged engine feature could map to specific torque calibration values, while an adaptive cruise control feature might map to region-specific speed thresholds. Drivetrain configurations can correspond to electronic stability control parameters. These mappings can include complex dependencies, ensuring that all relationships are accurately and precisely defined.

In the present embodiment, the feature-parameter mapping data 28 is automatically generated and updated. Scripting capabilities in pure::variants allow the application of rules such as, “If Feature X is selected, Parameter Y must have value Z.” Conditional logic and constraints enforce consistency and ensure the validity of the mappings. This approach facilitates the automatic generation of configuration files in formats like XML or JSON, which represent the feature-parameter mappings for specific product variants.

Once the mappings are generated, validation ensures there are no inconsistencies, such as unsatisfied dependencies or invalid parameter assignments. With validation complete, the feature-parameter mapping data can be exported to a usable format, such as a database or JSON file, for integration into downstream systems, including electronic control units or other software systems. Using pure::variants ensures that this entire process is consistent, scalable, and efficient, making it particularly effective for managing large-scale feature and parameter data across diverse product lines.

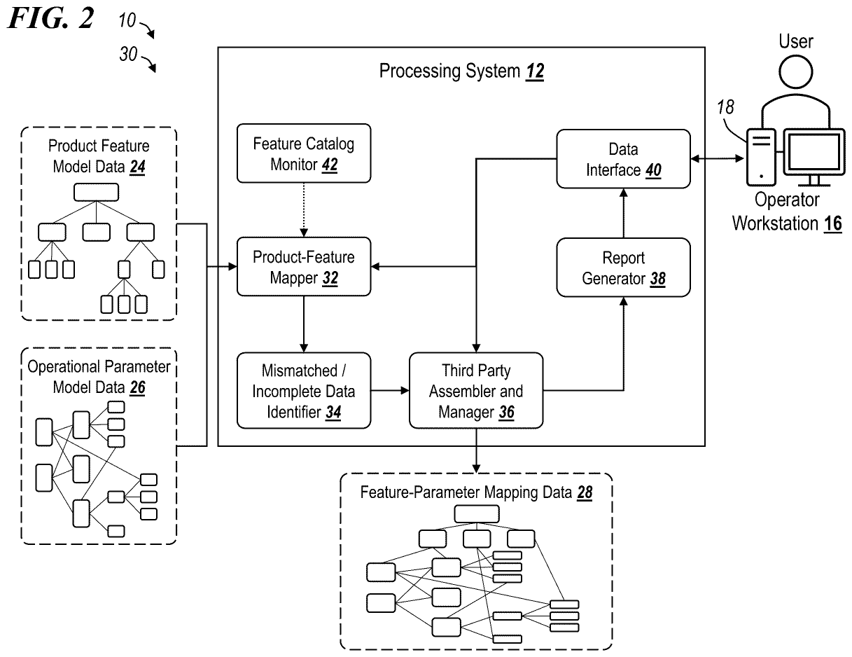

With reference to FIG. 2, there is shown the automated feature-parameter management system 10, including the processing system 12 and the operator workstation 16 being illustrated therein, along with a feature-parameter model generation framework 30 used for generating a feature-parameter model. In the present embodiment, a plurality of software modules 32-42 are used in order to generate the feature-parameter model data 28 (representing the feature-parameter model) using the product feature model data 24 and the operation parameter model data 26.

In the present embodiment, the plurality of software modules 32-42 are implemented by the processing system 12, particularly through execution by the at least one processor 20 of corresponding computer instructions (stored/retained in the memory 22). The software modules 32-42 may be implemented using any of a variety of programming languages, technologies, and techniques, such as JavaScript, Python, etc., running on a general-purpose computer, such as a desktop computer running Microsoft Windows™ or Linux™ as its operating system. In other embodiments, special-purpose computers may be manufactured so as to accommodate the particular processing involved in the associated software module 32-42. Those skilled in the art will appreciate the means for implementing each of the following software modules 32-42 in light of the following discussion and related teachings herein.

The feature-parameter model generation framework 30 is shown in FIG. 2 as having a configuration of the software modules 32-42 in a particular arrangement so as to facilitate or otherwise enable the generation of the feature-parameter model data 28 from the product feature model data 24 and the operational parameter model data 26.

At a start of such a processing framework 30, the product-feature mapper 32 generates mapping data, providing initial correspondences between features of the product feature model and corresponding operational parameters of the operational parameter model. The product-feature mapper 32 analyzes the relationships and dependencies defined within both models to create structured and accurate associations that reflect the intended configurations of a given product variant. By processing the data from the product feature model and operational parameter model, the mapper generates mapping data that ensures compatibility between the functional aspects of a product's features and the operational parameters governing its behavior. This module operates as a critical intermediary step, enabling subsequent stages of the framework to refine and validate the mappings, ensuring they meet design, regulatory, and functional requirements for diverse product configurations. Through this process, the mapper 32 contributes to the generation of a comprehensive and reliable feature-parameter model, facilitating efficient and accurate downstream system integration.

The product-feature mapper 32 can be implemented using pure::variants within the Eclipse™ IDE to streamline the generation of feature-parameter mapping data 28. In this implementation, the product feature model data 24, stored as a Microsoft Excel™ file, is imported into pure::variants using its built-in Excel™ import capabilities or compatible plugins. The tool processes the feature definitions, constraints, and variability points from the Excel™ file to construct a corresponding feature model within pure::variants. Similarly, the operational parameter model data 26 can be imported or represented within pure::variants, ensuring that all parameter definitions and dependencies are accurately captured. In some embodiments, such mapping processes are performed or facilitated by a domain expert. In some embodiments, initial mapping information is provided by a domain expert and then automatically evaluated.

The mapping process is executed using pure::variants' variant mapping capabilities, where relationships between features and parameters are defined and automated rules are applied to ensure alignment. Regular expression evaluation functions are integrated into the process to detect deviations in format and naming conventions within the mapping data, ensuring that all identifiers adhere to strict conventions. By enforcing consistent formats and naming rules, potential errors and inconsistencies in the feature-parameter mapping data 28 are minimized. The flexibility of the pure::variants data structure further enables seamless mapping of elements from the product feature model data 24 and the operational parameter model data 26, allowing users to identify critical run-time configuration values, such as (PRO.X.I) parameters, necessary to support vehicle and system configuration features.

The pure::variants platform itself provides advanced JavaScript application programming interfaces (APIs) that are leveraged in the implementation of the product-feature mapper 32. These APIs are used to access and process the feature-parameter mapping data 28, ensuring that all elements are systematically evaluated and their relationships with data in 24 and 26 are validated. The integration of these APIs into the mapping algorithm is a novel approach, enabling a seamless connection between the imported models and the final output. By automating the evaluation and validation process, pure::variants enhances the accuracy, efficiency, and reliability of the feature-parameter mapping data 28.

Once the mapping process is complete, the feature-parameter mapping data 28 is generated as an XML file using pure::variants' export functionality. This structured, machine-readable format facilitates integration into downstream systems. The process ensures that the feature-parameter mapping data 28 aligns with the requirements of existing environments, such as vehicle ordering systems, systems engineering workflows, and vehicle assembly plants, without requiring significant changes to these systems. By enabling the detection of inconsistencies or misalignments among the product feature model data 24, operational parameter model data 26, and feature-parameter mapping data 28, this implementation ensures consistent and accurate feature selection and configuration across all engineering teams. Leveraging pure::variants' robust modeling, validation, and automation capabilities, the workflow supports the efficient management of complex and scalable product configurations.

The mismatched/incomplete data identifier 34 is used for providing a systematic comparison of the exported data from the datasets represented by the product feature model data 24, the operational parameter model data 26, and the initial feature-parameter mapping data generated by the product-feature mapper 32. In one embodiment, a Python script is used, and begins by validating data integrity across all datasets by checking for duplicate entries in identifiers. Any duplicates may be logged as errors for traceability and subsequently ignored during the comparison process to avoid inaccuracies. The script may then process each element in the product feature model data 24 and compares it against the mapping information in the initial mapping data output by the product-feature mapper 32 in order to identify any mismatched or incomplete entries. The script may then evaluate this initial mapping information by cross-referencing it with the elements in the product feature model data 24 to ensure all features are correctly represented. Similarly, the script processes each element in the operational parameter model data 26 and compares it with the initial mapping information, while also ensuring that this mapping information aligns correctly with the elements in the operational parameter model. This bidirectional comparison guarantees that the feature-parameter mapping data is accurate, complete, and consistent, making it a critical step in validating the overall system's integrity and reliability.

The third-party assembler and manager 36 is designed to implement an algorithm that assembles and organizes third-party feature selection validation checks. This involves a sub-algorithm specifically tasked with organizing and assembling validation information to ensure consistency in third-party feature selection. Utilizing existing APIs, such as (for example) pure::variants™, the module evaluates the validation state of feature selection data by interfacing with external systems and retrieving relevant validation results. To optimize this process, the algorithm applies criteria to narrow the context and filter the elements included in the validation check, ensuring that only pertinent information is processed. In one embodiment, the APIs here are JavaScript commands developed by pure::systems (now PTC), and the system 10 uses these APIs in order to invoke, in a systematic way, the aforementioned third party feature selection validation checks. Specifically, at least in one embodiment, these APIs refer to JavaScript routines to run evaluations on specific parts of feature selection data and to capture the results in an exportable form. The pure::variants tool includes many validation checks and may be used for this purpose, according to an embodiment. This selective approach reduces unnecessary overhead and focuses on ensuring that third-party validations align with the system's defined feature dependencies and constraints. By consolidating and organizing this validation information, the third-party assembler and manager 36 provides a structured and efficient method for ensuring consistency and reliability in feature selection, particularly in environments involving external or third-party contributions.

The generated output feature-parameter mapping data 28 is structured as a web-based standard (e.g., native eXtensive Markup Language (XML)-based data model), specifically designed to enable the unique identification and integration of elements from the product feature model data 24 and the operational parameter model data 26. The data structure, referred to as the feature-parameter mapping model (and represented by the data 28), incorporates property values directly onto specific elements, thereby enabling these elements to reference and provide links between corresponding identifiers in the product feature model data 24 and the operational parameter model data 26. For the mapping to function effectively, the identifiers included in the feature-parameter mapping data 28 are to adhere to strict conventions regarding format, allowable characters and values, and structure to ensure consistency and compatibility. These identifiers are designed to be easily locatable in the product feature model data 24 and the operational parameter model data 26, enabling precise, automated cross-referencing and validation of relationships between product features and their associated operational parameters. A web-based standard is used for the feature-parameter mapping data 28, at least in the present embodiment, as such standards, such as, for example, XML or JavaScript Object Notation (JSON), results in a consistent and readily-parseable format. In embodiments, use of an XML-based format provides a flexible and machine-readable foundation for integrating the mapping data into downstream systems, supporting automation, scalability, and compliance with defined data standards.

The generated feature-parameter mapping data 28 is stored into long-term storage, particularly, a non-transitory, computer-readable memory provided as a part of the data storage system 14. The generated feature-parameter mapping data 28 may be stored at a central repository or data storage hosting platform, such as those supported by version control systems like Subversion or Git. The feature-parameter mapping data 28 may be also made available to a report generator 38, which is discussed more below.

The report generator 38 is used for generating reports pertaining to the feature-parameter mapping, and is shown as being communicatively coupled with the third party assembler and manager 36 and a data interface 40. In embodiments, the report generator 38 is designed to produce a comprehensive feature catalog validation status report, providing a centralized, easily accessible overview of feature-parameter mapping validation outcomes. In such embodiments, the report generator 38 may achieve this by processing input data from multiple sources, including the product-feature mapper, operational parameter model, and third-party validations. The report generator 38 may systematically analyze these datasets to identify invalid entries, and then organize this information into detailed, categorized lists that highlight specific elements within the feature-parameter mapping data 28 implicated in validation errors. Such lists may be formatted into comma separated value (CSV) or Excel™ files, and used for providing a clear and actionable summary of the validation status. Additionally, the report data may encompass broader insights, such as the frequency and types of errors, alignment with predefined rules and standards, and any patterns that may indicate systemic issues. By consolidating and processing this information, the report generator 38 supports efficient debugging, enhances traceability, and ensures the integrity of the feature-parameter mapping data 28 for downstream applications.

The data interface 40 is used for serving information from the processing system 12 and/or the data storage system 14 to the operator workstation 16. The data interface 40 is used for providing a well-defined and organized application programming interface (API) so as to permit access to the various data held by the processing system 12 and/or the data storage system 14. The data interface 40 is shown as being communicatively coupled to the report generator 38 so as to receive report data from the report generator 38; also, the data interface 40 is shown as being communicatively coupled to the operator workstation 16 in a bi-directional manner, so as to permit requests to be received at the data interface 40 from the operator workstation 16 and, vice versa, where requests are received at the operator workstation 16 from the data interface 40.

The data interface 40 may include hardware and networking elements such as high-speed network adapters, Ethernet connections, or fiber-optic links to support reliable and scalable data transfer capabilities, though it is not necessarily limited to these technologies. The data interface 40 may also utilize secure communication protocols and data transmission layers designed to minimize latency and ensure the integrity of the data being exchanged, such as using hypertext transmission protocol (HTTP) with transport layer security (TLS), for example. One or more of a variety of security measures, such as optional encryption and authentication mechanisms, may be incorporated to protect the confidentiality and accuracy of transmitted information. While the exact implementation of its hardware and software components may vary, the data interface 40 ensures effective and flexible communication to support workflows and enable efficient access to the report data generated by the report generator 38.

A feature catalog monitor 42 is provided and used for monitoring, modifications, new entries, or other updates or changes to the feature catalog data. In FIG. 2, the dotted lines represent access therebetween and, more particularly, indicating the feature catalog mapper 42 accesses the product feature model data 24, the operational parameter model data 26, and the feature-parameter mapping data 28 in order to perform is functionality, at least in the present embodiment. For example, the feature catalog monitor 42 continuously listens for data writes to the respective data 24, 26, 28 and, upon an indication of a change to said data in one of said three databases or sets 24, 26, 28, determines whether the data in the other ones (the other ones of 24, 26, 28) need to be updated or otherwise changed so as to accommodate and ensure workability of the system relative to the updated, new, or changed data.

The feature catalog monitor 42 is implemented using software executing on the at least one processor 20 of the processing system 12. In one embodiment, such as where the data 24, 26, 28 being monitored is stored in a relational database, a database trigger supported by the relational database manager (e.g., MySQL, PostegreSQL, SQL Server) may be used. In other embodiments, a change data capture (CDC), polling, event-driven notifications (e.g., MQTT (Message Queuing Telemetry Transport), Kafka™, RabbitMQ™), webhooks, operating system filesystem monitoring tools (e.g., inotify for Linux™, FileSystemWatcher for Windows™), and/or custom application logic may be used for implementing the automatic feature catalog monitoring.

When an update or change to the product feature model data 24 and/or the operational parameter model data 26, this event is identified by the feature catalog monitor 42 and used for initiating a feature-parameter mapping update process. This update process may be performed in order to ensure that the feature-parameter mapping data 28 is updated (if needed) appropriately in light of the changes to the data 24, 26. In this way, when a change to the data 24, 26 is performed (say by a manual edit or new entry provided by an operator, for example), the update process is executed in order to determine whether any updates are needed to the feature-parameter mapping data 28 and, if so, to then cause any such appropriate updates that may be needed to be applied. For example, when a first feature of the product feature model data 24 is modified or changed, operational parameter model data (which can be named “first operational parameter model data” and being at least a portion of the data 26) is then obtained where this first operational parameter model data is data representing a portion of the operational parameter model having correspondence with the first feature of the product feature model data 24. This corresponding (first) operational parameter model data is then evaluated in light of the changes (data indicating such changes) and/or the product feature model data 24 itself after having been changed, in order to determine what aspects of the operational parameter model data 26 are affected and, accordingly, to thereby identify a portion of the feature-parameter mapping data 28 (referred to as “first feature-parameter mapping data”) needing to be updated or changed so as to accommodate appropriately the update to the product feature model data 24.

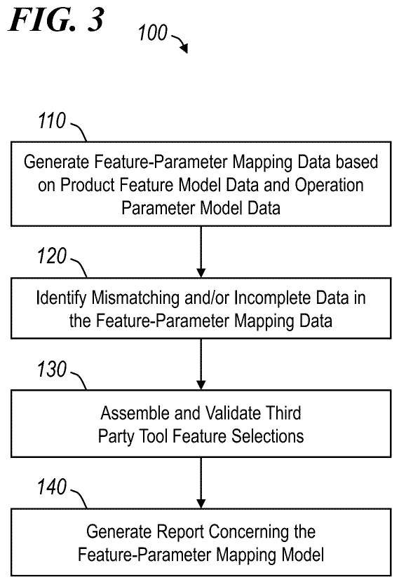

With reference to FIG. 3, there is shown a method 100, including a method of generating feature-parameter mapping data used for mapping aspects of a product feature model to those of an operational parameter model. The method 100 is carried out by the automated feature-parameter management system 10, particularly by the processing system 12, at least in one embodiment.

The method 100 begins with step 110, wherein feature-parameter mapping data is generated based on product feature model data and operational parameter model data. In one embodiment, the automated feature-parameter management system 10, using the processing system 12, integrates these two datasets into a unified feature-parameter model, and this may be performed in a semi-automatic or automatic manner. The semi-automatic embodiments are each considered an embodiment of the automated feature-parameter management system 10, as the term “automated” here refers to automation of aspects of the system, albeit fully or semi automatic.

In the automatic manner, no user input is used for generating feature-parameter mapping data as this data is generated based on product feature model data, operational parameter model data, and predetermined (often, highly specialized) domain knowledge information or data (referred to as predetermined domain knowledge). The predetermined domain knowledge refers to information or data indicative of specialized knowledge within the particular field or trade in which the system 10 is to be used for. The predetermined domain knowledge is stored in the memory 22 of the processing system 12, at least according to one embodiment. The predetermined domain knowledge may be initially received or otherwise obtained at the processing system 12 as a result of a domain expert entering specialized, trade-specific information into the client computer 18. In another embodiment, a machine learning (ML) model is trained using domain knowledge collected, aggregated, and/or otherwise provided by one or more domain experts. A variety of ML models may be used and, also, a variety of different training processes may be used as well, including, for example, artificial neural networks trained using supervised learning with the domain expert(s) providing supervision, support vector machines (SVMs), decision trees, random forests, Bayesian networks, reinforcement learning with expert demonstrations, transfer learning leveraging pre-trained models, graph neural networks (GNNs) for relational data, natural language processing (NLP) models for textual domain knowledge, and knowledge graphs integrating structured expert insights.

In the semi-automatic manner, user input from a domain expert is obtained at the operator workstation 16, and then provided to the product-feature mapper 32 and/or the third party assembler and manager 36 for use in generating the feature-parameter mapping data, such as via the data interface 40. The user input here includes domain knowledge informing how to piece together aspects of the product feature model data 24 and the operational parameter model data 26. In one embodiment, user inputs and other information used for this step may be retained, processed, and aggregated into a training dataset that is used for training a ML model that may be used in place of the domain expert at a later time, for example, when an automatic embodiment is used. In some embodiments, a ML model is trained and used for corroborating mapping information (or other domain knowledge) provided by the domain expert—such embodiments are still considered semi-automatic as user input is used for determining such mappings between the product feature model data 24 and the operational parameter model data 26.

The product feature model data 24 is structured hierarchically, where features and their relationships are represented, and this may include mandatory, optional, or alternative configurations. The operational parameter model data 26 represents technical parameters, such as ECU configurations, software interface definitions, or specific versioning information. In embodiments, the data modeling and handling capabilities of pure::variants (such as through its plugin-version offered in Eclipse™ IDE) is leveraged and used for defining explicit relationships and variability rules between features and operational parameters.

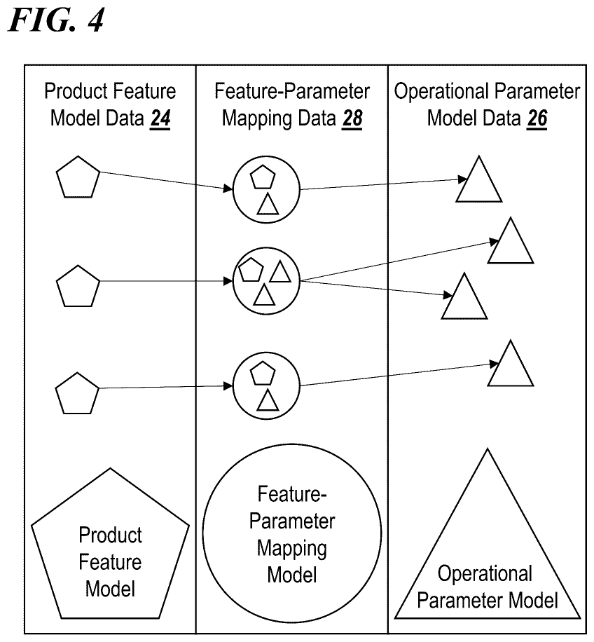

With reference to FIG. 4, there is shown a diagrammatic illustration of an example of feature-parameter mapping data 28 being used for linking or establishing (functional) relationships between the product feature model data 24 and the operational parameter model data 26. In particular, in the exemplary illustration of FIG. 4, a pentagon is used for representing data items formatted and/or structured according to the product feature model, a triangle is used for representing data items formatted and/or structured according to the operational parameter model, and a circle is used for representing data items formatted and/or structured according to the feature-parameter mapping model. The example of FIG. 4 depicts three product feature model data items being mapped to four operational parameter data items by virtue of the feature-parameter mapping data 28, particularly, through feature-parameter mapping data items, three of which are shown and used in the present example. In particular, in this example, a first feature-parameter mapping data item is used for mapping a first product feature model data item to a first operational parameter model data item; a second feature-parameter mapping data item is used for mapping a second product feature model data item to both a second and a third operational parameter model data item; and a third feature-parameter mapping data item is used for mapping a third product feature model data item to a fourth operational parameter model data item.

With reference back to FIG. 3, in step 110, a variety of programming mechanisms may be used implementing and/or defining such relationships and/or constraints. In one embodiment, regular expression evaluation functions are employed to verify the integrity of format and naming conventions in the mapping data. These functions detect deviations from predefined standards or definitions, for example, deviations in format and/or naming conventions in mapping data. Any issues identified during this step may be flagged for correction or further review. Once the mapping data is validated, all relevant data may be exported in any of a variety of forms or formats, such as, for example, into a tabular format. The method 100 continues to step 120.

In step 120, mismatching and/or incomplete data is identified for the feature-parameter mapping data. After the feature-parameter mapping data is initially generated using the feature-parameter mapper 32, this data is processed by the mismatched/incomplete data identifier 34 in order to identify any incomplete entries or data, mismatching data, mis-structured, and/or other errant issues with the data generated by the feature-parameter mapper 32. As discussed above, in one embodiment, a Python script is used to validate data integrity across each of the three datasets 24, 26, 28 by checking for duplicate entries in identifiers. For example, as discussed above, the script may then process each element in the product feature model data 24, comparing or otherwise evaluating it against the feature-parameter mapping information contained in the feature-parameter mapping data generated by the product-feature mapper 32. Also, in a similar manner, the script may be used to process each element in the operational parameter model data 26, comparing or otherwise evaluating it against the initial mapping information. The method 100 continues to step 130.

In step 130, third party tool feature selections are assembled and validated using a third party tool. The third-party assembler and manager 36 is used, at least in one embodiment, to perform this step, particularly through organizing and assembling validation information, particularly third-party feature-selection validation information, to ensure consistency in third-party feature selections. The feature selections constituting the third party tool feature selections are received from, for example, a user, such as a human operator of the client computer 18, for example. In another embodiment, the third party tool feature selections are received from a computer system automatically, such as in response to a predetermined trigger, which may be set by a user of the client computer 18, for example. The third-party assembler and manager 36 may be used to evaluate the validation state of feature selection data by interfacing with external systems and retrieving relevant validation results. The method 100 continues to step 140.

In step 140, a report is generated concerning the feature-parameter mapping model. The report includes information concerning the feature-parameter mapping model, and this report may include any of a variety of data or information derived or otherwise obtained from the feature-parameter mapping data 28, as well as from the product feature model data 24 and/or the operational parameter model data 26. As discussed above, data of the report (the “report data”) is or includes comprehensive feature catalog validation status information regarding the status and/or outcomes of the feature-parameter mapping and validation checks, such as those in steps 120 and 130.

The output of the report generator 38 may be one or more computer files that embodies the report (having the report data contained therein), and these computer files may be transported from the processing system 12 to the operator workstation 16 via the data interface 40 of the processing system 12. The operator workstation 16 includes the operator or client computer 18, which includes at least one human-machine interface (HMI) output device (e.g., a computer monitor/electronic display or audio speakers) that allows the computer 18 to communicate the information contained in the report to a human (operator) at the operator workstation 16. The method 100 ends.

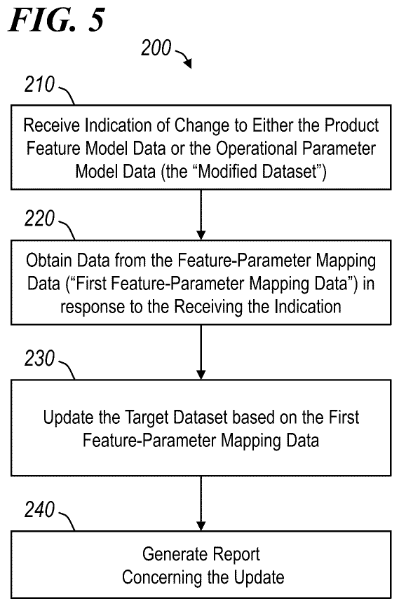

With reference to FIG. 5, there is shown a method 200, including a method of updating feature-parameter mapping data used for mapping aspects of a product feature model to those of an operational parameter model. The method 200 is carried out by the automated feature-parameter management system 10, particularly by the processing system 12, at least in one embodiment.

The method 200 begins with step 210, wherein an indication of a change to either the product feature model data or the operational parameter model data is received. In this step, the indication indicates a change to only one of (not both) the product feature model data or the operational parameter model data, and this changed data is referred to as the “modified dataset”. The other one of these datasets is referred to as the “target dataset”, as it is the one for which a determination is to be made as to whether to modify, change, or otherwise update any entries therein in response to the modifications or change to the modified dataset. For example, a change may be detected to the operational parameter model data 26 and, in such an embodiment, the modified dataset is the operational parameter model data 26 and the target dataset is the feature product model data 24. Likewise, in another embodiment, a change may be detected to the feature product model data 24 and, in such an embodiment, the modified dataset is the feature product model data 24 and the target dataset is the operational parameter model data 26.

In one embodiment, the indication is received from the operator workstation 16 in response to user input by a (human) operator, such as through inputting updated or new information for the modified dataset (either the data 24 or 26) at the client computer 18, which may then be sent to the processing system 12 and received at its data interface 40. Such an indication, being spawned or otherwise triggered by manual (human) intervention, is referred to as a manual indication, which is distinguishable from an automated indication; here, the automated indication is when such an indication is spawned or otherwise triggered without a user/operator (human) input or intervention, such as through use of the feature catalog monitor 42, as discussed above. The method 200 continues to step 220.

In step 220, data is obtained from the feature-parameter mapping data in response to receiving the indication in step 210. This feature-parameter mapping data is a subset of the feature-parameter mapping data 28 and is referred to as first feature-parameter mapping data.

In some embodiments where the modified dataset is the feature product model data 24, the indication indicates one or more features affected by the change to the feature product model data 24. The one or more affected features are thus used for determining which portion or data items of the feature-parameter mapping data 28 are to be retrieved and used for determining whether to update the operational parameter model data 26, such as by identifying one or more operational parameters linked or having a causative or functional relationship with the identified (affected) feature(s).

In some embodiments where the modified dataset is the operational parameter model data 26, the indication indicates one or more operational parameters affected by the change to the operational parameter model data 26. The one or more affected operational parameters are thus used for determining which portion or data items of the feature-parameter mapping data 28 are to be retrieved and used for determining whether to update the feature product model data 24, such as by identifying one or more features linked or having a causative or functional relationship with the identified (affected) operational parameter(s). The method 200 continues to step 230.

In step 230, the target dataset is updated according to the changes in the modified dataset and as a result of (or based on) the first feature-parameter mapping data determined in step 220. The identified data item(s) of the target dataset, which may be identified feature(s) or identified operational parameter(s), are then updated in accordance with the first feature-parameter mapping data (obtained in step 220) and the change(s) to the modified dataset. Also, in embodiments, the feature-parameter mapping data 28 is updated based on the updates to the modified dataset and/or the target dataset. For example, the feature-parameter mapper 32 is used for changing entries in the feature-parameter model data 28 in order to appropriately reflect changes to the modified dataset and the target dataset. The method 200 continues to step 240.

In step 240, a report concerning the update to the target dataset is generated and may be provided to an operator. The report includes report data concerning information affected by the operations of step 230 in which data items of the target dataset were added, removed, modified, or otherwise changed. The report can include any information regarding automatic operations performed as a part of the steps 210-230, such as identifying which data items were changed (in the modified dataset, the target dataset, and/or the feature-parameter mapping data). The report may be provided to a (human) operator, such as by sending the report to the client computer 18 of the operator workstation 16 via the data interface 40 of the processing system 12. The method 200 then ends.

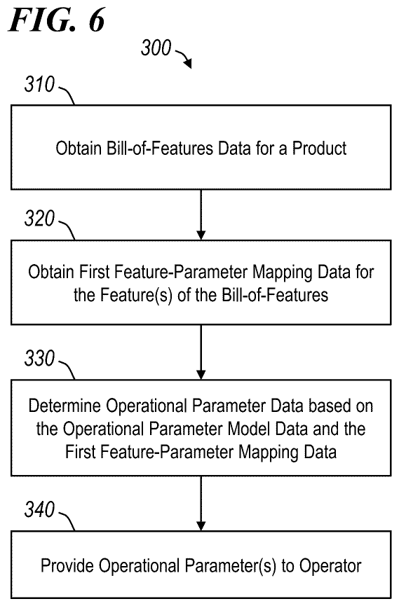

With reference to FIG. 6, there is shown a method 300 of automatically determining operational parameter(s) for a product (steps 310-330) and providing the operational parameter(s) to an operator (steps 310-340). The method 300 is carried out by the automated feature-parameter management system 10, particularly by the processing system 12, at least in one embodiment.

The method 300 begins with step 310, wherein bill-of-features data for a product is obtained using the product feature model data and an operator input indicating a set of features. For example, in one embodiment, the (human) operator uses the client computer 18 input information indicating the set of features, and then provided from the client computer 18 to the processing system 12 via the data interface, which may use an internet or local area connection, for example. In another embodiment, the set of features is received at the data interface 40 automatically from another computer system. In one embodiment, the third party tool, pure::variants™, is operated in order to facilitate and/or effect generation of bill-of-features data based on the operator input. The method 300 continues to step 320.

In step 320, first feature-parameter mapping data for the feature(s) of the bill-of-features data (step 310) is obtained. For example, the feature(s) are identified, such as by a unique identifier, and then the feature-parameter mapping data is queried for said identifier(s), and the corresponding or associated feature-parameter mapping data may be recalled from the data storage system 14 and obtained by the processing system 12. The method 300 continues to step 330.

In step 330, operational parameter data is determined based on operational parameter model data and the first feature-parameter mapping data. For example, the first feature-parameter mapping data is used for identifying which operational parameters are affected or implicated (or potentially affected or implicated) by the selected/identified feature(s). Such operational parameters may be recalled from the data storage system 14 and obtained by the processing system 12. The method 300 continues to step 340.

In step 340, the operational parameter(s) are provided to an operator, such as the operator of the operator workstation 16 through sending the operational parameter data (indicating the operational parameter(s)) to the client computer 18 via the data interface 40. The operational parameter(s) may then be viewed and evaluated by one or more operators, and used for development or assessment of product manufacturing, development, and/or releases. The method 300 ends.

The term “and/or” is to be construed as an inclusive OR. Therefore, for example, the phrase “A, B, and/or C” is to be interpreted as covering all of the following: “A”; “B”; “C”; “A and B”; “A and C”; “B and C”; and “A, B, and C.”

What is claimed is:

1. An automated feature-parameter management system, comprising:
a data storage system being comprised of non-transitory, computer-readable memory, and being used for storing product feature model data, operational parameter model data, and feature-parameter mapping model data; and
a computer system having at least one electronic processor and memory storing computer instructions, wherein the computer system, when the computer instructions are executed by the at least one processor, is configured to:
obtain bill-of-features data for a product using the product feature model data, wherein the bill-of-features data indicates a first set of features for the product;
obtain first feature-parameter mapping data for the set of features for the product, wherein the first feature-parameter mapping data is obtained data from the feature-parameter mapping model data stored in the data storage system; and
determine operational parameter data based on the operational parameter model data and the first feature-parameter mapping data.

2. The system of claim 1, further comprising an operator workstation for communicating information between the automated feature-parameter management and an operator, wherein the computer system, when the computer instructions are executed by the at least one processor, is further configured to: provide the operational parameter data to the operator at the operator workstation.

3. The system of claim 2, further comprising receiving an operator input from the operator indicating the set of the features of the product.

4. The system of claim 1, wherein the feature-parameter mapping data is generated by identifying relationships between features of a product feature model used for structuring the product feature model data and an operational parameter model used for structuring the operational parameter model data, and wherein the relationships are identified based on domain knowledge provided by a user and/or predetermined domain knowledge.

5. The system of claim 1, wherein the first feature-parameter mapping data is a subset of the feature-parameter mapping data that is identified based on the set of features.

6. The system of claim 1, wherein the computer system, when the computer instructions are executed by the at least one processor, is further configured to: detect when a change is made to a modified dataset that is either the product feature model data or the operational parameter model data and, in response to detecting the change, determine whether to perform an update to a target dataset that is comprised of the other one of the product feature model data or the operational parameter model data.

7. The system of claim 6, wherein the computer system, when the computer instructions are executed by the at least one processor, is further configured to: provide a result of the determination of whether to perform the update to an operator.

8. The system of claim 6, wherein the computer system, when the computer instructions are executed by the at least one processor, is further configured to: automatically determine update data for updating the target dataset and automatically update the target dataset according to the update data.

9. The system of claim 1, wherein the computer system, when the computer instructions are executed by the at least one processor, is further configured to: identify mismatches and/or incomplete data in the feature-parameter mapping data after performing a mapping of at least a portion of the product feature model data to at least a portion of the operational parameter model data.

10. The system of claim 1, wherein the computer system, when the computer instructions are executed by the at least one processor, is further configured to: automatically generate a report concerning the feature-parameter mapping data after generating or updating the feature-parameter mapping data, and providing the report to an operator.

11. A method of determining operational parameter data for a product with a set of features, comprising:
obtaining bill-of-features data for a product using product feature model data, wherein the bill-of-features data indicates a first set of features for the product;
obtaining first feature-parameter mapping data for the set of features for the product, wherein the first feature-parameter mapping data is obtained data from feature-parameter mapping model data; and
determining operational parameter data based on operational parameter model data and the first feature-parameter mapping data.

12. The method of claim 11, further comprising receiving an operator input from the operator indicating the set of the features of the product.

13. The method of claim 11, wherein the feature-parameter mapping data is generated by identifying relationships between features of a product feature model used for structuring the product feature model data and an operational parameter model used for structuring the operational parameter model data, and wherein the relationships are identified based on domain knowledge provided by a user and/or predetermined domain knowledge.

14. The method of claim 11, wherein the first feature-parameter mapping data is a subset of the feature-parameter mapping data that is identified based on the set of features.

15. The method of claim 11, wherein the method further comprises: detecting when a change is made to a modified dataset that is either the product feature model data or the operational parameter model data and, in response to detecting the change, determining whether to perform an update to a target dataset that is comprised of the other one of the product feature model data or the operational parameter model data.

16. The method of claim 15, wherein the method further comprises: providing a result of the determination of whether to perform the update to an operator.

17. The method of claim 15, wherein the method further comprises: automatically determining update data for updating the target dataset and automatically updating the target dataset according to the update data.

18. The method of claim 11, wherein the method further comprises: identify mismatches and/or incomplete data in the feature-parameter mapping data after performing a mapping of at least a portion of the product feature model data to at least a portion of the operational parameter model data.

19. The method of claim 11, wherein the method further comprises: automatically generate a report concerning the feature-parameter mapping data after generating or updating the feature-parameter mapping data, and providing the report to an operator.

20. The method of claim 11, wherein the method is performed by a computer system having at least one electronic processor and memory storing computer instructions, wherein the computer system, when the computer instructions are executed by the at least one processor, is configured to carry out the method.
